(19) United States
(12) Patent Application Publication
(10) Pub. No.: US 2024/0173852 A1
(43) Pub. Date: May 30, 2024

(54) SUBSTRATE ATTACHING/DETACHING ROBOT, SUBSTRATE ATTACHING/DETACHING METHOD, AND FILM FORMATION APPARATUS

(71) Applicant: Resonac Corporation, Tokyo (JP)

(72) Inventor: Takayuki MORI, Tokyo (JP)

(21) Appl. No.: 18/505,581

(22) Filed: Nov. 9, 2023

(30) Foreign Application Priority Data
Nov. 28, 2022 (JP) 2022-189303

(51) Int. Cl. B25J 9/10; C23C 16/458; G11B 5/84

(52) U.S. Cl. CPC B25J 9/1085; C23C 16/4583; G11B 5/84

(57) ABSTRACT

Breakage of various parts during attaching or detaching of a substrate is inhibited. A substrate attaching/detaching robot includes a substrate holding member configured to hold a substrate, a robot arm configured to move the substrate holding member, and at least three line-shaped members connecting the substrate holding member and an end of the robot arm. The three line-shaped members are made of a shape-memory alloy. A temperature of the substrate holding member during attaching or detaching of the substrate onto or from a substrate holder configured to hold the substrate in a detachably attachable manner is in a range of a shape recovery temperature of the shape-memory alloy.

### CROSS-REFERENCE TO RELATED APPLICATION

The present application is based on and claims priority under 35 U.S.C. § 119 to Japanese Patent Application No. 2022-189303, filed on Nov. 28, 2022, the contents of which are incorporated herein by reference in their entirety.

### BACKGROUND OF THE INVENTION

### 1. Field of the Invention

The present disclosure relates to a substrate attaching/detaching robot, a substrate attaching/detaching method, and a film formation apparatus.

### 2. Description of the Related Art

Hitherto, a substrate attaching/detaching robot configured to attach or detach a substrate has been known. A substrate attaching/detaching method for attaching or detaching a substrate, and a film formation apparatus configured to perform film formation processes on a substrate have also been known (for example, see Japanese Laid-Open Patent Application Publication No. 2010-222700).

### SUMMARY OF THE INVENTION

However, according to Japanese Laid-Open Patent Application Publication No. 2010-222700, there may be a case where the substrate attaching/detaching robot pushes a substrate against a supporting member situated on a substrate holder with an excessive force, and an end portion of the substrate is hence damaged by the supporting member. Moreover, there may be a case where a substrate supporting member situated on the substrate attaching/detaching robot accidentally contacts a substrate or the substrate holder, and various parts become broken due to the impact of the contact.

Hence, in view of the problems described above, an object of the technique of the present disclosure is to inhibit breakage of various parts during attaching or detaching of a substrate.

According to an embodiment of the present disclosure, a substrate attaching/detaching robot, including:
a substrate holding member configured to hold a substrate;
a robot arm configured to move the substrate holding member; and
at least three line-shaped members connecting the substrate holding member and an end of the robot arm
is provided.

The three line-shaped members are made of a shape-memory alloy.

A temperature of the substrate holding member during attaching or detaching of the substrate onto or from a substrate holder configured to hold the substrate in a detachably attachable manner is in a range of a shape recovery temperature of the shape-memory alloy.

According to another embodiment of the present disclosure, a substrate attaching/detaching method, including:
connecting, as preparation, a substrate holding member configured to hold a substrate and an end of a robot arm configured to move the substrate holding member, using at least three line-shaped members made of a shape-memory alloy;
setting, as preparation, a temperature of the substrate holding member during attaching or detaching of the substrate in a range of a shape recovery temperature of the shape-memory alloy;
inserting the substrate holding member into an opening in the substrate to make the substrate holdable by the substrate holding member; and
attaching or detaching the substrate onto or from a substrate holder configured to hold the substrate in a detachably attachable manner
is provided.

According to another embodiment of the present disclosure, a film formation apparatus, including:
a chamber in which a film formation process is performed on a substrate;
a carrier on which a substrate holder is situated, the substrate holder being configured to hold the substrate in a detachably attachable manner;
a conveying mechanism configured to convey the carrier; and
a substrate attaching/detaching robot according to an embodiment of the present disclosure, the substrate attaching/detaching robot being configured to attach or detach the substrate onto or from the substrate holder
is provided.

According to an embodiment of the present disclosure, it is possible to inhibit breakage of various parts during attaching or detaching of a substrate.

### BRIEF DESCRIPTION OF THE DRAWINGS

FIG. 1 is a cross-sectional view of an example of a recording medium produced by a film formation apparatus according to an embodiment;

FIG. 2 is a plan view of the film formation apparatus according to then embodiment;

FIG. 3 is a side view of a chamber of the film formation apparatus according to the embodiment;

FIG. 4 is a side view of a substrate holder of the film formation apparatus according to the embodiment;

FIG. 5 is a side view of a main part of a substrate attaching/detaching robot according to an embodiment;

FIG. 6A is a front view of the main part of the substrate attaching/detaching robot according to the embodiment;

FIG. 6B is a side view of the main part of the substrate attaching/detaching robot according to the embodiment; and

FIG. 7 is a process chart illustrating a schematic procedure of a substrate attaching/detaching method according to an embodiment.

### DESCRIPTION OF THE PREFERRED EMBODIMENTS

An embodiment of the present disclosure will be described in detail below with reference to the drawings. The same components will be denoted by the same reference numerals in the drawings, and overlapping descriptions about them will be omitted where appropriate.

In recent years, applicable ranges of magnetic recording apparatuses have significantly expanded and the importance of magnetic recording apparatuses has increased, while the recording density of magnetic recording media used with magnetic recording apparatuses has also been remarkably increasing.

Examples of the method for producing a magnetic recording medium include a method of forming, for example, a soft magnetic layer, an intermediate layer, and a recording magnetic layer on a non-magnetic substrate, and then forming a protective layer on the recording magnetic layer.

To the extent possible, it is preferable to continuously perform such a producing method using one film formation apparatus. Performing film formation processes continuously can inhibit contamination of substrates during handling, and can increase the magnetic recording medium productivity by reducing, for example, handling steps and improving the efficiency and the product yield of the production steps.

Hence, when producing such magnetic recording media, it is proposed to use an inline-type film formation apparatus configured to sequentially form, for example, magnetic layers on both surfaces of non-magnetic substrates while conveying a carrier holding a plurality of non-magnetic substrates sequentially from one chamber to another chamber of a plurality of chambers.

The inline-type film formation apparatus attaches or detaches a substrate onto or from a substrate holder by using a substrate attaching/detaching robot. During attaching or detaching, there may be a case where the substrate attaching/detaching robot pushes a substrate against a supporting member of the substrate holder with an excessive force, and an end portion of the substrate is hence damaged by the supporting member. Moreover, there may be a case where a substrate supporting member on the substrate attaching/detaching robot side accidentally collides with the substrate holder or a substrate, and the substrate supporting member becomes broken due to the impact of the collision.

In order to solve these problems, a substrate attaching/detaching robot according to an embodiment inhibits breakage of various parts during attaching or detaching of a substrate. The various parts include various parts constituting the film formation apparatus, and a substrate, which is the target on which films are formed.

The present embodiment will be described by taking, as an example, a case where magnetic recording media to be mounted on a hard disk device are produced using an inline-type film formation apparatus configured to perform film formation processes while conveying disk-shaped substrates sequentially from a chamber to another chamber of a plurality of chambers.

(Magnetic recording medium)

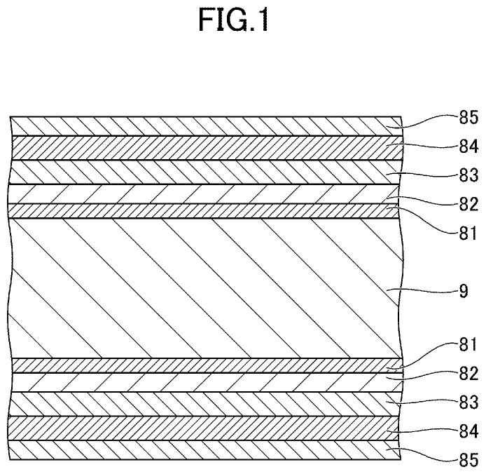

FIG. 1 is a cross-sectional view of an example of a recording medium produced by a film formation apparatus according to an embodiment. The recording medium is, for example, a magnetic recording medium.

A magnetic recording medium has a structure including soft magnetic layers 81, intermediate layers 82, recording magnetic layers 83, and protective layers 84 in this order on both surfaces of a disk-shaped substrate 9, and further including lubricating films 85 on the outermost surfaces.

As the disk-shaped substrate 9, an Al alloy substrate made of, for example, an Al—Mg alloy mainly containing Al, or a typical substrate made of any one selected from, for example, soda glass, aluminosilicate-based glass, various types of crystallized glass, silicon, titanium, ceramics, and various types of resins is used. That is, a desirably selected substrate can be used as the disk-shaped substrate 9 so long as it is a non-magnetic substrate.

### (Configuration of Inline-Type Film Formation Apparatus)

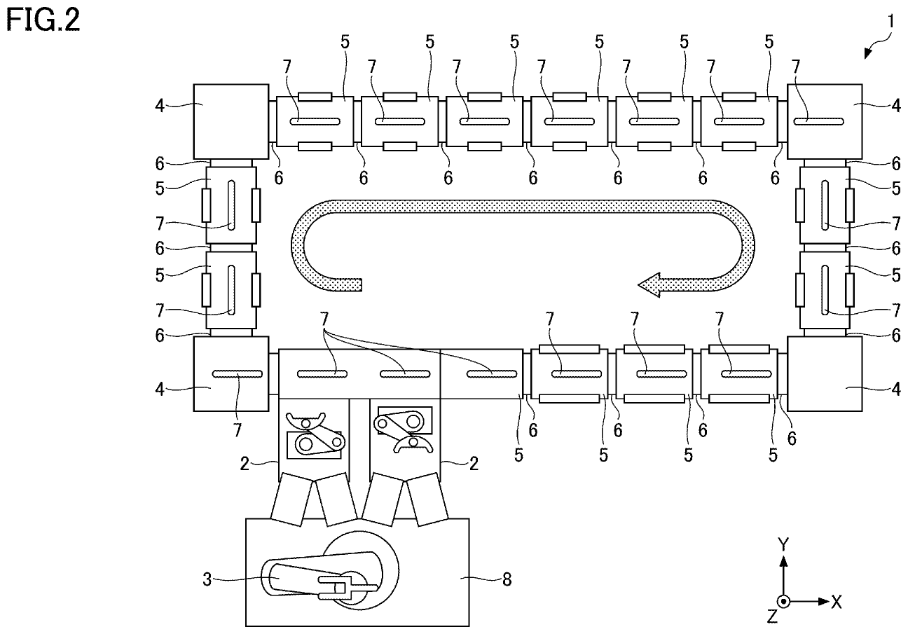

FIG. 2 is a plan view of an inline-type film formation apparatus 1 according to an embodiment. When producing a magnetic recording medium, at least soft magnetic layer 81, intermediate layers 82, recording magnetic layers 83, and protective layers 84 are laminated in this order on both surfaces of the disk-shaped substrate 9, which is the target on which films are formed, using, for example, the inline-type film formation apparatus 1 as illustrated in FIG. 2. Through these steps, magnetic recording media can be obtained at a high productivity.

Specifically, the inline-type film formation apparatus 1 includes a robot table 8, a substrate cassette transferring/placing robot 3 placed on the robot table 8, a substrate attaching/detaching robot 2 adjacent to the robot table 8, and a plurality of corner chambers 4 in which a carrier 7 is rotated. The inline-type film formation apparatus 1 also includes a plurality of chambers 5 positioned between a corner chamber 4 and a corner chamber 4, and a plurality of carriers 7 to be conveyed through the plurality of corner chambers 4 and the plurality of chambers 5.

Gate valves 6 are situated at coupling portions between the chambers 5. When the gate valves 6 are closed, the interiors of the chambers 5 become tightly closed spaces independent from each other.

Non-illustrated vacuum pumps are coupled to the respective chambers 5. The plurality of carriers 7 are sequentially conveyed by a conveying mechanism into the chambers 5 that are depressurized by operations of the vacuum pumps. While the plurality of carriers 7 are sequentially conveyed, soft magnetic layers 81, intermediate layers 82, recording magnetic layers 83, and protective layers 84 are formed in this order on both surfaces of disk-shaped substrates 9 held on the carriers 7 in the respective chambers 5.

After the protective layers 84 are formed, the disk-shaped substrates 9 are taken out from the inline-type film formation apparatus 1, lubricating films 85 are formed on both surfaces of the disk-shaped substrates 9, and magnetic recording media illustrated in FIG. 1 are obtained ultimately. The corner chambers 4 are chambers in which the travelling direction of the carriers 7 is changed. A mechanism configured to rotate the carrier 7 and transfer the carrier 7 to the next chamber 5 is situated inside the corner chamber 4.

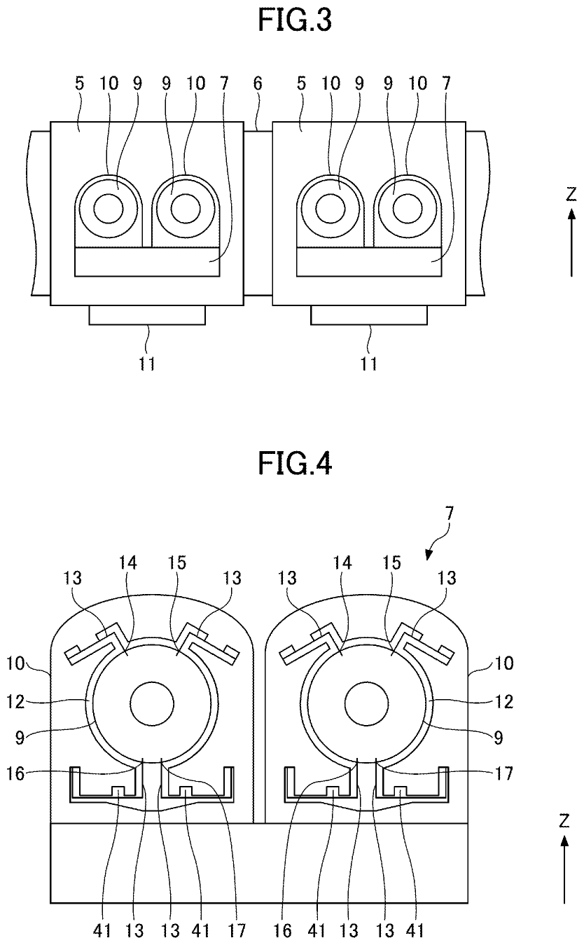

FIG. 3 is a side view of a chamber 5 of a film formation apparatus according to an embodiment. The inline-type film formation apparatus 1 includes a conveying mechanism 11 configured to convey the carrier 7. For example, a contactlessly driving-linear motor driving mechanism is used as the conveying mechanism 11.

As the linear motor driving mechanism, a plurality of magnets are situated in lower portions of the carriers 7 such that N poles and S poles are arranged alternately, and rotating magnets on which N poles and S poles are arranged spirally and alternately are situated below the magnets of the carriers 7 via a partition wall and along a conveying path. The linear motor driving mechanism conveys the carriers 7 by rotating the rotating magnets about their axes while magnetically coupling the magnets on the carriers 7 side and the rotating magnets contactlessly.

### (Configuration of Substrate Holder)

FIG. 4 is a side view of a substrate holder 10 of a film formation apparatus according to an embodiment. The carrier 7 includes two substrate holders 10 each configured to hold a disk-shaped substrate 9 upright. “Upright” means a state in which a main surface (an external surface or a back surface) of the disk-shaped substrate 9 is in parallel with the direction of gravity. In the carrier 7, the two substrate holders 10 are arranged in one line in the conveying direction.

The substrate holder 10 has a thickness that is approximately from one through a few times greater than the thickness of the disk-shaped substrate 9. A circular-shaped hole portion 12 having a diameter greater than that of the disk-shaped substrate 9 is bored in the substrate holder 10 such that a radial-direction gap of approximately 10 mm is formed from the circumferential end of the disk-shaped substrate 9 that is held. The substrate holder 10 holds the disk-shaped substrate 9 in the hole portion 12 formed in the substrate holder 10 in a detachably attachable manner.

Four supporting members 13 are attached elastically-deformably on the periphery of the hole portion 12 of the substrate holder 10. The four supporting members 13 support corresponding circumferential end portions of the disk-shaped substrate 9 that is positioned within the hole portion 12.

Vertical-direction upper two supporting members 13 of the four supporting members 13 support a first-side circumferential end portion 14 that is at a vertical-direction upper position and a second-side circumferential end portion 15 that is at a vertical-direction upper position, respectively. Vertical-direction lower two supporting members 13 of the four supporting members 13 support a third-side circumferential end portion 16 that is at a vertical-direction lower position and a fourth-side circumferential end portion 17 that is at a vertical-direction lower position, respectively.

In FIG. 4, the first-side circumferential end portion 14 and the third-side circumferential end portion 16 are left-hand-side circumferential end portions, and the second-side circumferential end portion 15 and the fourth-side circumferential end portion 17 are right-hand-side circumferential end portions. However, when FIG. 4 is seen from the back, they are on the opposite sides.

The substrate holder 10 holds the disk-shaped substrate 9 fitted within the hole portion 12 in a detachably attachable manner by supporting the disk-shaped substrate 9 by the four supporting members 13.

The supporting members 13 are, for example, plate spring members bent in an L-letter shape. A base end of each supporting member 13 is fixed on the body of the substrate holder 10. The four supporting members 13 are situated in four paths formed on the periphery of the hole portion 12 of the substrate holder 10. A forefront end of each supporting member 13 projects inward into the hole portion 12. A V-letter groove or a U-letter groove engageable with the circumferential end of the disk-shaped substrate 9 is provided in the forefront end of each supporting member 13 in order to inhibit falling of the disk-shaped substrate 9. In the present embodiment, four supporting members 13 are used. However, in order to hold the disk-shaped substrate 9, the number of supporting member 13 needs only to be 3 or greater.

For the supporting members 13, for example, iron, stainless steel, Inconel, nickel, cobalt, molybdenum, and tungsten, and an alloy mainly containing any of these may be used. The supporting force exerted by the supporting members 13 on the disk-shaped substrate 9 may be appropriately selected in accordance with, for example, the material and the thickness of the disk-shaped substrate 9, yet is in the range of, for example, from 2 N through 6 N.

Releasing holes 41 are provided in lower two paths of the four paths formed on the periphery of the hole portion 12, respectively. Two releasing rods configured to push the lower two supporting members 13 downward to release the disk-shaped substrate 9 from being supported by the supporting members 13 are inserted into the two releasing holes 41.

### (Configuration of Substrate Attaching/Detaching Robot)

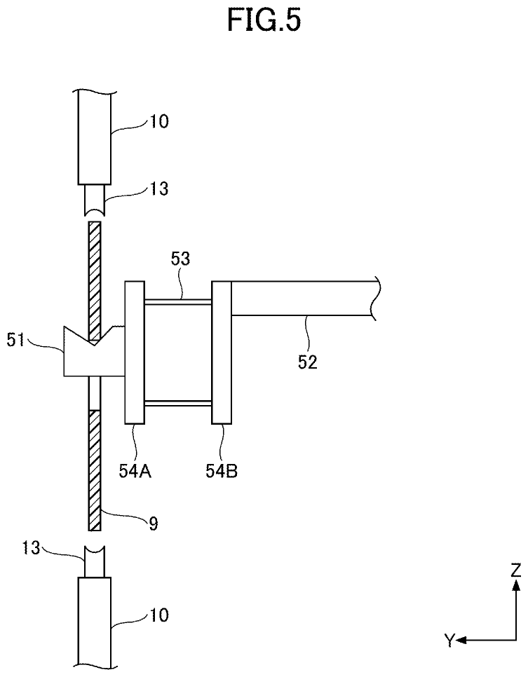

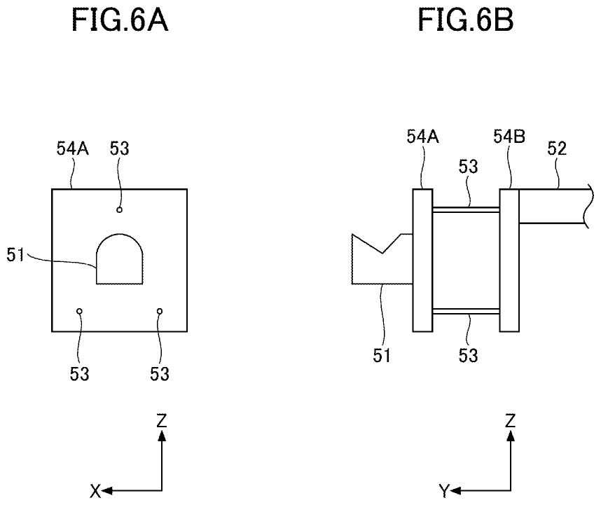

FIG. 5 is a side view of a main part of a substrate attaching/detaching robot 2 according to an embodiment. FIG. 6A is a front view of a main part of a substrate attaching/detaching robot 2 according to an embodiment. FIG. 6B is a side view of a main part of a substrate attaching/detaching robot 2 according to an embodiment.

The substrate attaching/detaching robot 2 is, for example, an articulated robot. The substrate attaching/detaching robot 2 includes a substrate holding member 51, a robot arm 52, and at least three line-shaped members 53 connecting the substrate holding member 51 and an end of the robot arm 52. The substrate attaching/detaching robot 2 also includes a first plate-shaped member 54A on which the substrate holding member 51 is fixed, and a second plate-shaped member 54B fixed on the end of the robot arm 52.

The substrate holding member 51 is configured to hold the disk-shaped substrate 9. The substrate holding member 51 holds the disk-shaped substrate 9 by, for example, being inserted into an opening in the disk-shaped substrate 9 and hanging the disk-shaped substrate 9 thereon. In a side view perspective, the substrate holding member 51 has a V-letter groove, and hangs the disk-shaped substrate 9 thereon by locking the disk-shaped substrate 9 in the V-letter groove.

The robot arm 52 is a robot arm having joints in at least one or more axes. The robot arm 52 is configured to transfer the substrate holding member 51 to a position and an attitude that are previously instructed.

The three line-shaped members 53 are each fixed on the first plate-shaped member 54A at one end thereof, and fixed on the second plate-shaped member 54B on the other end thereof. The three line-shaped members 53 connect the first plate-shaped member 54A and the second plate-shaped member 54B directly. However, they may connect the substrate holding member 51 and the end of the robot arm 52 directly.

The three line-shaped members 53 are positioned in parallel with one another between a main surface of the first plate-shaped member 54A and a main surface of the second plate-shaped member 54B. The main surface of the first plate-shaped member 54A and the main surface of the second plate-shaped member 54B are positioned in parallel with each other.

Three fixing holes are formed in each of the first plate-shaped member 54A and the second plate-shaped member 54B in a surrounding region of a region on which the substrate holding member 51 is fixed. The three line-shaped members 53 are each inserted, at one end thereof, into a corresponding one of the three fixing holes in the first plate-shaped member 54A. The three line-shaped members 53 are each inserted, at the other end thereof, into a corresponding one of the three fixing holes in the second plate-shaped member 54B.

As the material of the substrate holding member 51, the first plate-shaped member 54A, and the second plate-shaped member 54B, an alloy mainly containing any selected from, for example, iron, aluminum, nickel, cobalt, molybdenum, and tungsten may be used.

On the other hand, all of the three line-shaped members 53 are made of a shape-memory alloy. As the shape-memory alloy, any one material selected from, for example, NiTi-based alloys, NiTiCo-based alloys, and NiTiCu-based alloys may be used. It is particularly preferable to use a NiTi-based alloy. When using a NiTi-based alloy, it is preferable to set the shape recovery temperature of the three line-shaped members 53 in a range of from 20° ° C. through 80° C.

By the three line-shaped members 53 being made of such a shape-memory alloy, the temperature at which the substrate holding member 51 is actually used is included in the range of the shape recovery temperature of the shape-memory alloy. Hence, it is possible to obtain an effect of returning the substrate holding member 51 to its original position. The original position of the substrate holding member 51 means the initial position of the substrate holding member 51 at the design phase.

For example, the length, the line diameter, and the number of the line-shaped members 53 may be appropriately selected in accordance with the size and the weight of the disk-shaped substrate 9. For example, when the substrate attaching/detaching robot 2 simultaneously holds two disk-shaped substrates 9 having an outer diameter of 95 mm (approximately 3.5 inches), an inner diameter of 25 mm, and a thickness of 1 mm and made of an aluminum alloy, line-shaped members 53 that are made of a NiTi alloy and can be used in such a case have a length of approximately from 5 mm through 30 mm and a line diameter of approximately from 0.3 mm through 2 mm.

### (Substrate Attaching/Detaching Method)

The substrate attaching/detaching robot 2 takes out a disk-shaped substrate 9, which is the target on which films are formed, from a substrate cassette, conveys the disk-shaped substrate 9 to the carrier 7, and attaches the disk-shaped substrate 9 on the substrate holder 10. The substrate attaching/detaching robot 2 also takes out a disk-shaped substrate 9, which has been through film formation processes, from the substrate holder 10, conveys the disk-shaped substrate 9, which has been through film formation processes, to the substrate cassette, and attaches the disk-shaped substrate 9, which has been through film formation processes, on the substrate cassette.

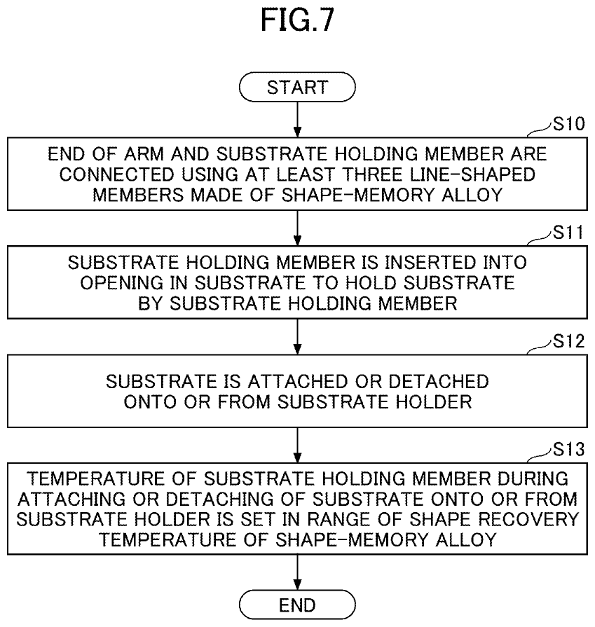

A schematic procedure of a substrate attaching/detaching method according to the present disclosure will be described with reference to FIG. 7. FIG. 7 is a process chart illustrating a schematic procedure of a substrate attaching/detaching method according to an embodiment. The order of the steps illustrated in FIG. 7 is non-limiting. Moreover, because the step S10 and the step S13 are preparation steps, the step S10 and the step S13 do not need to be performed every time when attaching or detaching a substrate, and need only to be performed once at the very beginning.

### <Step S10>

First, in a preparation step, the substrate holding member 51 and an end of the robot arm 52 of the substrate attaching/detaching robot 2 are connected using the at least three line-shaped members 53 made of a shape-memory alloy. For example, a main surface of the first plate-shaped member 54A on which the substrate holding member 51 is fixed and a main surface of the second plate-shaped member 54B fixed on the robot arm 52 are fixed with respect to each other using the three line-shaped members 53 made of a shape-memory alloy. That is, the substrate holding member 51 and an end of the robot arm 52 are indirectly connected using the three line-shaped members 53.

### <Step S11>

Next, in a holding step, the substrate attaching/detaching robot 2 brings a disk-shaped substrate 9 into a state holdable by the substrate holding member 51. For example, the substrate attaching/detaching robot 2 inserts the substrate holding member 51 into an opening in the disk-shaped substrate 9 to make the disk-shaped substrate 9 holdable by the substrate holding member 51.

For example, when attaching a disk-shaped substrate 9 on the substrate holder 10, the substrate attaching/detaching robot 2 inserts the substrate holding member 51 into the opening in a disk-shaped substrate 9 that is in the substrate cassette, and holds the disk-shaped substrate 9 by the substrate holding member 51. On the other hand, when detaching a disk-shaped substrate 9 from the substrate holder 10, the substrate attaching/detaching robot 2 inserts the substrate holding member 51 into the opening in the disk-shaped substrate 9 that is on the substrate holder 10, and makes the disk-shaped substrate 9 holdable by the substrate holding member 51.

When inserting the substrate holding member 51 into the opening in a disk-shaped substrate 9, the substrate attaching/detaching robot 2 moves the substrate holding member 51 such that the substrate holding member 51 does not contact a portion of the disk-shaped substrate 9 that is offset from the opening in the disk-shaped substrate 9. However, even if the substrate holding member 51 contacts the disk-shaped substrate 9, the three line-shaped members deform and absorb the impact of the contact, making it possible to inhibit breakage of the disk-shaped substrate 9 or the substrate holding member 51. Moreover, because the substrate holding member 51 returns to its original position under the shape-memory effect of the three line-shaped members, the substrate attaching/detaching robot 2 does not lose control on the position of the substrate holding member 51 or control on the attitude of the substrate holding member 51.

### <Step S12>

Next, in the attaching/detaching step, the substrate attaching/detaching robot 2 attaches or detaches the disk-shaped substrate 9 onto or from the substrate holder 10.

When attaching a disk-shaped substrate 9 on the substrate holder 10, any other apparatus different from the substrate attaching/detaching robot 2 inserts two releasing rods into the two releasing holes 41, respectively, to push the lower two supporting members 13 downward. The substrate attaching/detaching robot 2 inserts the disk-shaped substrate 9 held by the substrate holding member 51 into the hole portion 12 of the substrate holder 10. By the two releasing rods being withdrawn by the any other apparatus to return the supporting members 13 to the original positions, the disk-shaped substrate 9 becomes supported by the plurality of supporting members 13, and the disk-shaped substrate 9 is attached on the substrate holder 10.

When detaching a disk-shaped substrate 9 from the substrate holder 10, the any other apparatus inserts two releasing rods and pushes the supporting members 13 downward, to release the disk-shaped substrate 9 from being supported by the supporting members 13. The substrate attaching/detaching robot 2 hangs and holds the disk-shaped substrate 9 on the substrate holding member 51, and takes out the disk-shaped substrate 9 from the substrate holder 10 such that the disk-shaped substrate 9 do not collide with the plurality of supporting members 13.

When attaching and detaching a disk-shaped substrate 9 onto and from the substrate holder 10, the substrate attaching/detaching robot 2 moves the substrate holding member 51 such that the disk-shaped substrate 9 do not contact the plurality of supporting members 13 or the body of the substrate holder 10. However, even if the disk-shaped substrate 9 contacts the supporting members 13 or the body of the substrate holder 10, the three line-shaped members deform and absorb the impact of the contact, making it possible to inhibit breakage of the disk-shaped substrate 9 or the substrate holder 10. Moreover, because the substrate holding member 51 returns to its original position under the shape-memory effect of the three line-shaped members, the substrate attaching/detaching robot 2 does not lose control on the position of the substrate holding member 51 or control on the attitude of the substrate holding member 51.

### <Step S13>

In a preparation step, the temperature of the substrate holding member 51 during attaching or detaching of a disk-shaped substrate 9 is set in a range of the shape recovery temperature of the shape-memory alloy constituting the three line-shaped members 53. The control on the temperature of the substrate holding member 51 may be performed by a substrate loading chamber or a substrate unloading chamber in which the substrate attaching/detaching robot 2 exists, may be performed by a substrate attaching chamber or a substrate detaching chamber in which the carrier 7 exists, or may be performed by the substrate attaching/detaching robot 2 itself.

By the temperature of the substrate holding member 51 during attaching or detaching of a disk-shaped substrate 9 being set in the range of the shape recovery temperature of the shape-memory alloy, the three line-shaped members not only can deform and absorb the impact of a contact on various parts, but also can return the substrate holding member 51 to the original position. This ultimately leads to being able to inhibit breakage of various parts such as a disk-shaped substrate 9, the substrate holding member 51, and the substrate holder 10.

For example, when the carrier 7 stops at a wrong position before attaching or detaching of a disk-shaped substrate 9 and the hole portion 12 of the substrate holder 10 does not exist where it should be, there may be a case where the substrate holding member 51 contacts a portion of the disk-shaped substrate 9 that is offset from the opening in the disk-shaped substrate 9, or the disk-shaped substrate 9 contacts the substrate holder 10. However, by deformation of the line-shaped members 53, the impact of the contact is absorbed and breakage of various parts is inhibited. Moreover, because the substrate holding member 51 returns to its original position under the shape-memory effect of the line-shaped members 53, the substrate attaching/detaching robot 2 does not lose control on the position of the substrate holding member 51 or control on the attitude of the substrate holding member 51.

In contrast, some existing techniques employ a substrate holding member having an easily elastically-deformable structure, as a measure against breakage during attaching or detaching of a substrate. However, the strength of such a structure is low, and the substrate holding member may fail to return to its original position.

Moreover, when existing techniques fail to stop a carrier at the right position before attaching or detaching of a substrate to make the substrate holding member contact a portion of the disk-shaped substrate that is offset from the opening in the disk-shaped substrate or to make the disk-shaped substrate contact the substrate holder, there may be a case where various parts break due to the impact of the contact and the substrate holding member 51 does not return to its original position.

### Workings and Effects

According to the substrate attaching/detaching robot 2 described above, the substrate holding member 51 and an end of the robot arm 52 are connected by the at least three line-shaped members 53 made of a shape-memory alloy, and the temperature of the substrate holding member 51 during attaching or detaching of a disk-shaped substrate 9 is set in the range of the shape recovery temperature of the shape-memory alloy.

Hence, the range in which the substrate holding member 51 can be displaced is wide, and the substrate holding member 51 can return to its original position under the shape-memory effect of the line-shaped members 53. A disk-shaped substrate 9 is inhibited from being pushed against the supporting members 13 of the substrate holder 10 with an excessive force, and the circumferential end of the disk-shaped substrate 9 is inhibited from being damaged by the supporting members 13.

Even if the substrate holding member 51 accidentally contacts a disk-shaped substrate 9 or the substrate holder 10, the substrate holding member 51 absorbs the impact by deformation of the line-shaped members 53, and the line-shaped members 53 can return the substrate holding member 51 to the original position.

That is, by the temperature of the substrate holding member 51 during attaching or detaching of a disk-shaped substrate 9 being set in the range of the shape recovery temperature of the line-shaped members 53, the line-shaped members 53 can recover their shapes and return the substrate holding member 51 to the original position.

The preferred embodiment has been described in detail above. However, the embodiment described above is non-limiting, and various modifications and replacements are applicable to the embodiment described above without departing from the scope described in the claims.

For example, the substrate attaching/detaching robot according to the present disclosure is not limited to a robot arm form, and may be a robot of any other form, such as a humanoid. The film formation apparatus according to the present disclosure is not limited to an inline-type film formation apparatus, and may be a film formation apparatus of any other form, such as a batch-type film formation apparatus. A substrate according to the present disclosure is not limited to a substrate for a magnetic recording medium, and may be a silicon wafer for a semiconductor wafer.

All of the numerals such as ordinal numbers and quantities used in the description of the embodiment described above have been presented as examples for concretely describing the technique of the present disclosure, and the present disclosure is not limited to the numerals presented as examples. The connection relationship between the components has been presented as an example for concretely describing the technique of the present disclosure, and the connection relationship for realizing the functions of the present disclosure is not limited to this.

What is claimed is:

1. A substrate attaching/detaching robot, comprising:
a substrate holding member configured to hold a substrate;
a robot arm configured to move the substrate holding member; and
at least three line-shaped members connecting the substrate holding member and an end of the robot arm,
wherein the three line-shaped members are made of a shape-memory alloy, and
a temperature of the substrate holding member during attaching or detaching of the substrate onto or from a substrate holder configured to hold the substrate in a detachably attachable manner is in a range of a shape recovery temperature of the shape-memory alloy.

2. The substrate attaching/detaching robot according to claim 1,
wherein the shape-memory alloy is a NiTi-based alloy, and the range of the shape recovery temperature is from 20° ° C. through 80° C.

3. A substrate attaching/detaching method, comprising:
connecting, as preparation, a substrate holding member configured to hold a substrate and an end of a robot arm configured to move the substrate holding member, using at least three line-shaped members made of a shape-memory alloy;
setting, as preparation, a temperature of the substrate holding member during attaching or detaching of the substrate in a range of a shape recovery temperature of the shape-memory alloy;
inserting the substrate holding member into an opening in the substrate to make the substrate holdable by the substrate holding member; and
attaching or detaching the substrate onto or from a substrate holder configured to hold the substrate in a detachably attachable manner.

4. A film formation apparatus, comprising:
a chamber in which a film formation process is performed on a substrate;
a carrier on which a substrate holder is situated, the substrate holder being configured to hold the substrate in a detachably attachable manner;
a conveying mechanism configured to convey the carrier; and
the substrate attaching/detaching robot of claim 1, the substrate attaching/detaching robot being configured to attach or detach the substrate onto or from the substrate holder.
